(19) United States
(12) Patent Application Publication
(10) Pub. No.: US 2026/0068071 A1
(43) Pub. Date: Mar. 5, 2026

(54) SLIDING RAIL SECURING DEVICE

(71) Applicant: FOSITEK CORPORATION, New Taipei City (TW)

(72) Inventors: Chia-Hung SU, New Taipei City (TW); Hao-Ping WANG, New Taipei City (TW)

(73) Assignee: FOSITEK CORPORATION, New Taipei City (TW)

(21) Appl. No.: 19/002,876

(22) Filed: Dec. 27, 2024

(30) Foreign Application Priority Data
Sep. 4, 2024 (TW) 113133511

(51) Int. Cl. H05K 7/14

(52) U.S. Cl. CPC H05K 7/1489

(57) ABSTRACT

A sliding rail securing device includes a rear support rail having two rear side walls, and a rear bracket module including a rear bracket, at least one rear lock member, and at least one rear installation unit. At least one of the rear side walls is formed with a slide groove, and the at least one rear lock member has a protrusion movably engaged with the slide groove. The at least one rear lock member is movable relative to the rear support rail along a rear axis extending in a front-rear direction to drive the protrusion to move along the slide groove, such that the at least one rear lock member is driven to pivot between a normal position and a pivoted position.

### CROSS-REFERENCE TO RELATED APPLICATION

This application claims priority to Taiwanese Invention Patent Application No. 113133511, filed on Sep. 4, 2024, the entire disclosure of which is incorporated by reference herein.

### FIELD

The disclosure relates to a sliding rail securing device, and more particularly to a tool-less sliding rail securing device.

### BACKGROUND

A conventional sliding rail securing device is used for securing a sliding rail onto a server cabinet. The conventional sliding rail securing device includes a securing member mounted to a rear end thereof. The conventional sliding rail securing device is operated by having a user pivot the securing member to a position where the conventional sliding rail securing device is engaged with the server cabinet. However, it is inconvenient to mount the conventional sliding rail securing device to a rear rack of the server cabinet as two operators are required; one of the operators is proximate to the rear rack in order to be able to operate the securing member for engagement, and the other operator holds the conventional sliding rail securing device to keep it in position. Hence, there is room for improvement.

### SUMMARY

Therefore, an object of the disclosure is to provide a sliding rail securing device that can alleviate at least one of the drawbacks of the prior art.

According to the disclosure, the sliding rail securing device is adapted for mounting a sliding rail to a rear mount bracket of a cabinet. The sliding rail securing device includes a rear support rail and a rear bracket module. The rear support rail has a rear base wall and two rear side walls. The rear base wall has a front end and a rear end that is opposite to the front end in a front-rear direction, and a slide surface that is disposed between the front end and the rear end. The rear side walls extend respectively and transversely from opposite top and bottom sides of the slide surface. At least one of the rear side walls is formed with a slide groove that extends away from the slide surface and towards the rear end of the rear base wall. The rear bracket module includes a rear bracket, at least one rear lock member, and at least one rear installation unit. The rear bracket is movably disposed on the rear support rail. The at least one rear lock member is pivotably disposed on the rear bracket, is adapted to be engaged with the rear mount bracket, and has a protrusion that is movably engaged with the slide groove of the at least one of the rear side walls. The at least one rear installation unit is mounted to the rear bracket and is adapted to be engaged with the rear mount bracket. When the rear bracket module is in an unlocked state and is disposed in front of the rear mount bracket, the at least one rear lock member is rearwardly movable relative to the rear support rail along a rear axis extending in the front-rear direction to drive the protrusion to move along the slide groove, such that the at least one rear lock member is driven to pivot away from the rear bracket from a normal position to a pivoted position. The at least one rear lock member is further rearwardly movable relative to the rear support rail along the rear axis for engaging the at least one rear installation unit with the rear mount bracket. When the at least one rear installation unit is engaged with the rear mount bracket, the at least one rear lock member is forwardly movable relative to the rear support rail along the rear axis and opposite to the front-rear direction to drive the protrusion to move along the slide groove, such that the at least one rear lock member is driven to pivot from the pivoted position to the normal position for being engaged with the rear mount bracket and converting the rear bracket module from the unlocked state to a locked state.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an embodiment of a sliding rail securing device according to the disclosure mounted to a front mount bracket and a rear mount bracket and connected to a sliding rail.

FIG. 2 is another perspective view of the embodiment, the sliding rail, the front mount bracket and the rear mount bracket.

FIG. 3 is a partially exploded perspective view of the embodiment, the sliding rail, the front mount bracket and the rear mount bracket.

FIG. 4 is a perspective view of a rear support rail of the embodiment.

FIG. 5 is a partially exploded perspective view of the rear support rail.

FIG. 6 is a fragmentary side view of the rear support rail.

FIG. 7 is a perspective view of a rear bracket module of the embodiment.

FIG. 8 is a partially exploded perspective view of the rear bracket module.

FIG. 9 is an exploded perspective view of a rear installation unit of the rear bracket module.

FIG. 10 is a perspective view of a front support rail of the embodiment.

FIG. 11 is a fragmentary front view of the front support rail and the rear support rail.

FIG. 12 is a fragmentary top view of the front support rail and the rear support rail, illustrating an obstruction protrusion of the front support rail engaging a through hole of the rear support rail.

FIG. 13 is a perspective view of a front bracket module of the embodiment.

FIG. 14 is a top view of the front bracket module.

FIG. 15 is a partially exploded perspective view of the front bracket module.

FIG. 16 is an exploded perspective view of a front installation unit of the front bracket module.

FIGS. 17 to 19 are fragmentary top perspective views of the rear bracket module and the rear mount bracket, and illustrate a process of engaging the rear bracket module with the rear mount bracket.

FIGS. 20 to 22 are fragmentary top perspective views of the front bracket module and the front mount bracket, and illustrate a process of engaging the front bracket module with the front mount bracket.

FIG. 23 is a fragmentary side view of the front bracket module and the front mount bracket, illustrating two front square installation members extending through two front mount holes of the front mount bracket when each of the front mount holes has a square shape.

FIG. 24 is a fragmentary sectional view of the embodiment taken along line XXIV-XXIV in FIG. 23.

FIG. 25 is a fragmentary side view of the front bracket module and the front mount bracket, illustrating two front cylindrical installation members extending through the front mount holes of the front mount bracket when each of the front mount holes has a circular shape.

FIG. 26 is a fragmentary sectional view of the embodiment taken along line XXVI-XXVI in FIG. 25.

FIG. 27 is a fragmentary side view of the front bracket module and the front mount bracket, illustrating two front screw members extending through the front mount holes of the front mount bracket when each of the front mount holes is a threaded hole.

FIG. 28 is a fragmentary sectional view of the embodiment taken along line XXVIII-XXVIII in FIG. 27.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

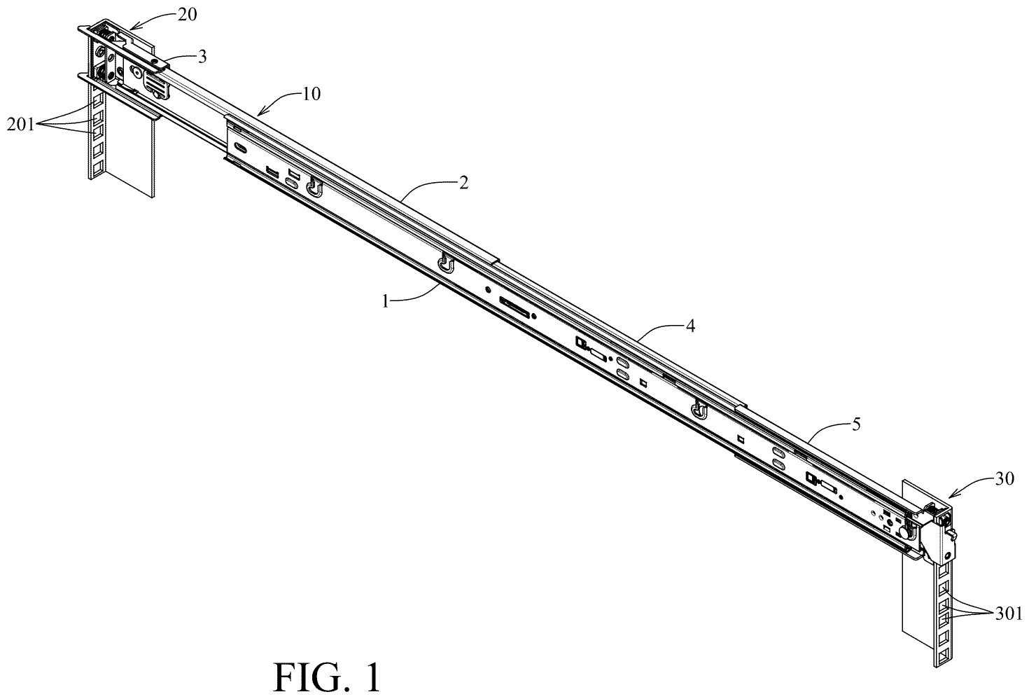

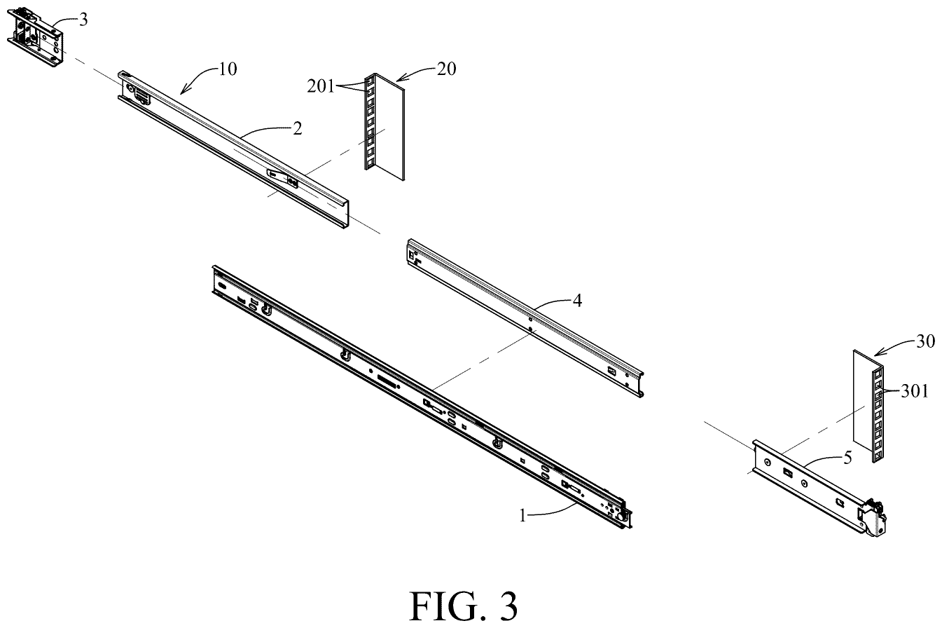

Referring to FIGS. 1 to 3, an embodiment of a sliding rail securing device 10 according to the disclosure is adapted for mounting a sliding rail 1 to a front mount bracket 30 and a rear mount bracket 20 of a cabinet (not shown). The front mount bracket 30 is formed with a plurality of front mount holes 301, and the rear mount bracket 20 is formed with a plurality of rear mount holes 201. The sliding rail securing device 10 includes a rear support rail 2, a rear bracket module 3, a front support rail 4, and a front bracket module 5.

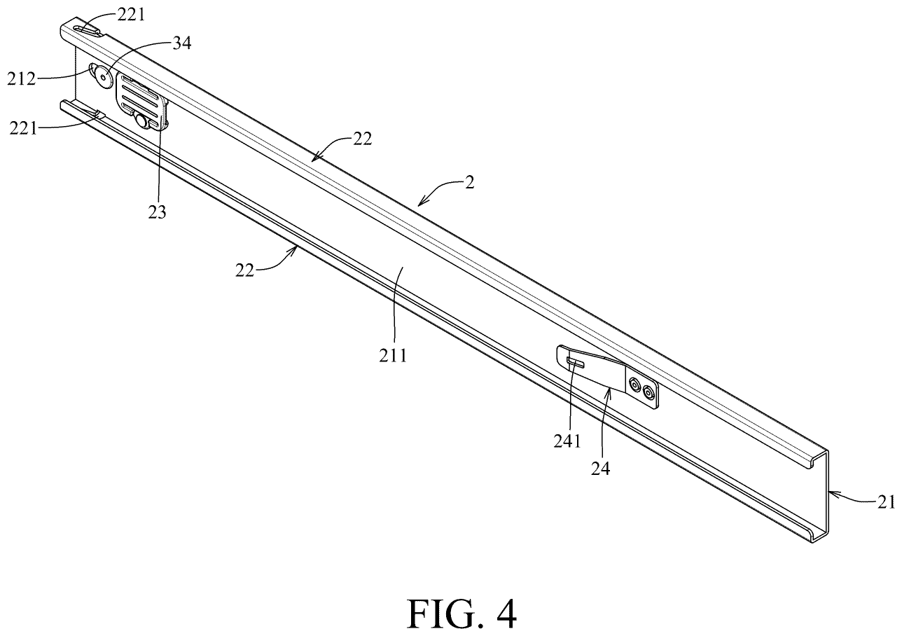

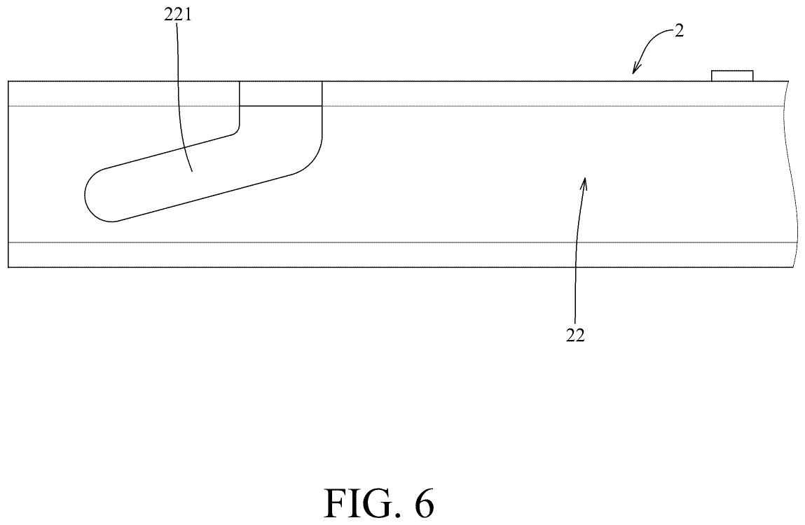

Referring to FIGS. 4 to 6, the rear support rail 2 has a rear base wall 21 having a front end and a rear end that is opposite to the front end in a front-rear direction, and a slide surface 211 that is disposed between the front end and the rear end, two rear side walls 22 extending respectively and transversely from opposite top and bottom sides of the slide surface 211, a positioner member 23 disposed on the slide surface 211, and a stop member 24 disposed on the slide surface 211 and spaced apart from the positioner member 23. The rear base wall 21 is formed with two position grooves 212. At least one of the rear side walls 22 is formed with a slide groove 221 that extends away from the slide surface 211 and towards the rear end of the rear base wall 21. The stop member 24 extends away from the slide surface 211, and has a through hole 241. In this embodiment, each of the rear side walls 22 is formed with a slide groove 221.

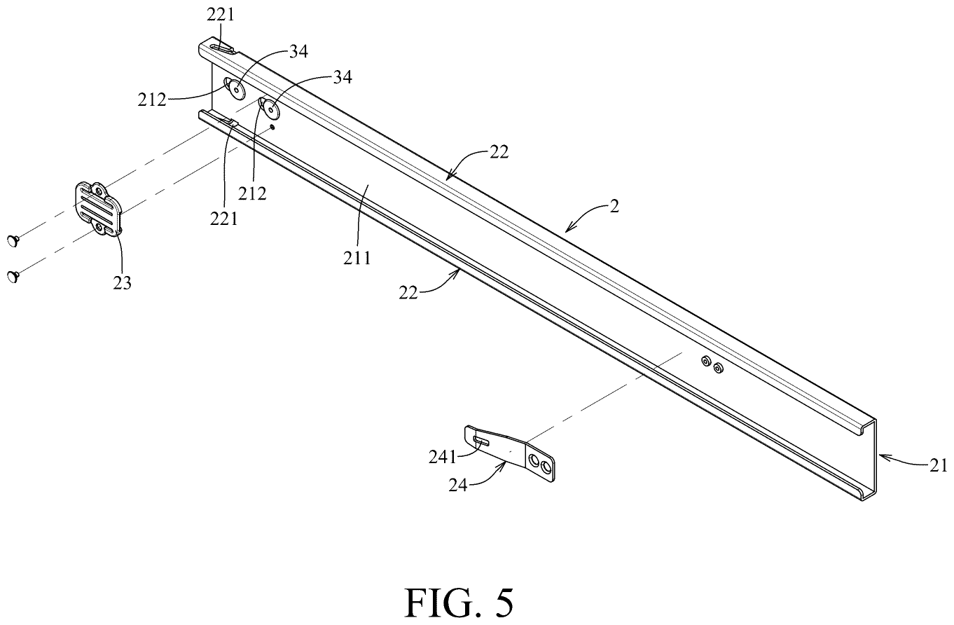

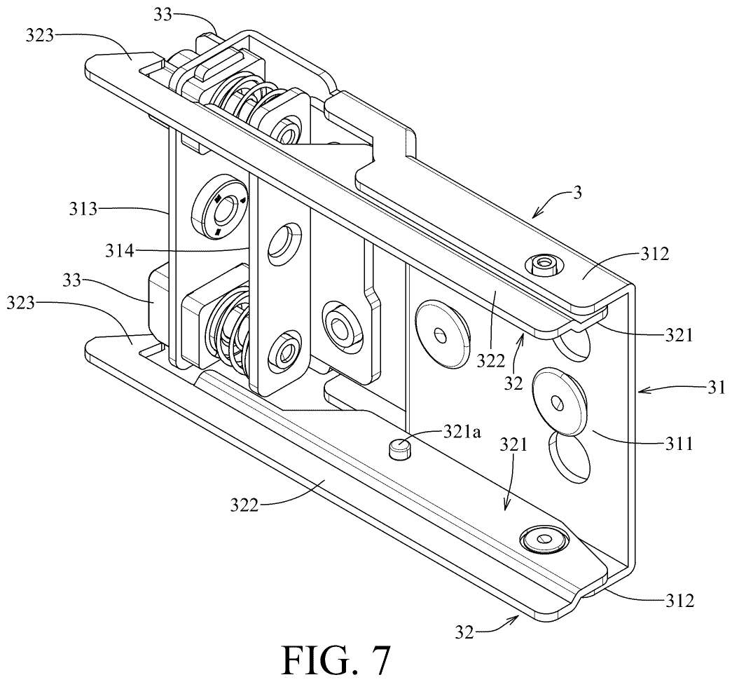

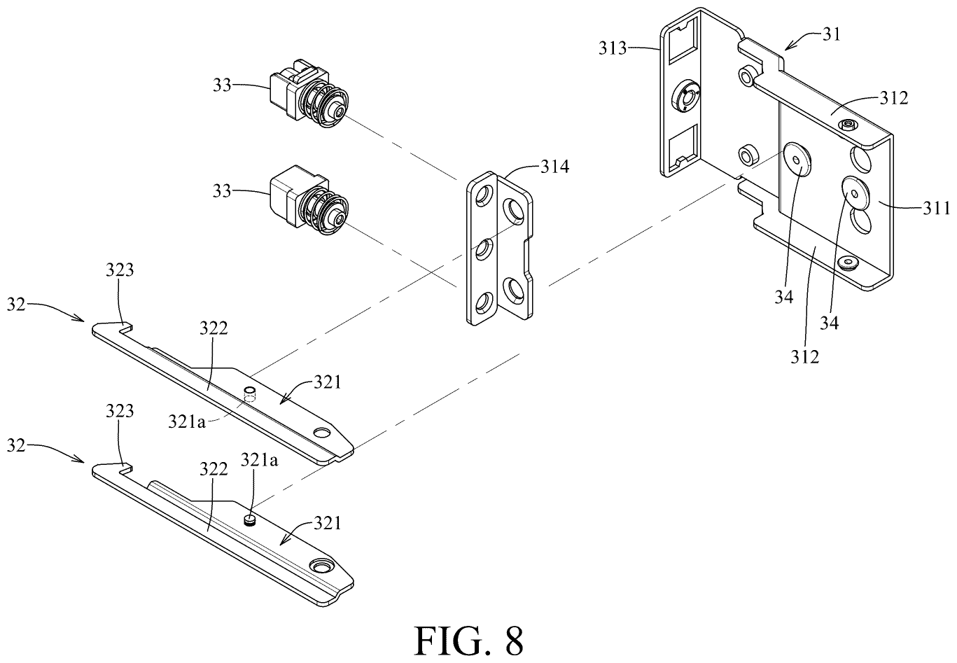

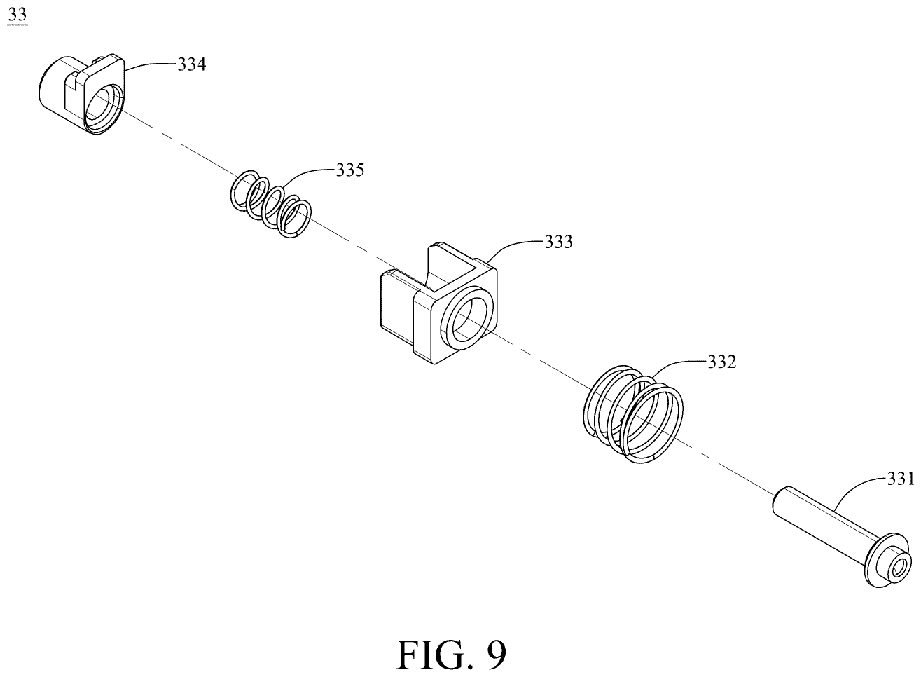

Referring to FIG. 5 and FIGS. 7 to 9, the rear bracket module 3 includes a rear bracket 31 movably disposed on the rear support rail 2, at least one rear lock member 32 pivotably disposed on the rear bracket 31, at least one rear installation unit 33 mounted to the rear bracket 31 and adapted to be engaged with the rear mount bracket 20 via the rear mount holes 201, and two limit members 34. The rear bracket 31 includes a rear base plate 311, two rear side plates 312 extending respectively and transversely from opposite top and bottom sides of the rear base plate 311, a rear abutment plate 313 extending transversely from an end of the rear base plate 311 that is opposite to the rear support rail 2, and a rear installation plate 314 mounted to the rear base plate 311 and spaced apart from the rear abutment plate 313. In this embodiment, both a number of the at least one rear lock member 32 and a number of the at least one rear installation unit 33 are two. Each of the limit members 34 extends through a respective one of the position grooves 212 and the rear base plate 311. The positioner member 23 covers one of the position grooves 212 and one of the limit members 34. The one of the limit members 34 abuts against the positioner member 23. Each of the rear lock members 32 is adapted to be engaged with the rear mount bracket 20, and has a connection portion 321 that is pivotably connected to the rear bracket 31, an extension portion 322 that extends from the connection portion 321 away from the rear bracket 31, and a hook portion 323 that extends rearwardly from a rear end of the extension portion 322. The rear side plates 312 are respectively connected to the connection portions 321 of the rear lock members 32. Each of the rear lock members 32 further has a protrusion 321a that is formed on the connection portions 321, and that is movably engaged with a respective one of the slide grooves 221 of the rear side walls 22. It should be noted that, the number of the rear lock members 32 and a number of the slide grooves 221 are not limited to two, and may be not less than one in other embodiments.

Referring to FIGS. 1, 8, and 9, the rear installation units 33 are mounted on the rear installation plate 314 and extend through the rear abutment plate 313. Each of the rear installation units 33 includes a rear screw member 331 that extends through the rear abutment plate 313 and the rear installation plate 314, and that has a head portion abutting against the rear installation plate 314. Each of the rear installation unit 33 further includes a first rear resilient member 332 that is sleeved on the rear screw member 331, a rear square installation member 333 that extends through the rear abutment plate 313, a rear cylindrical installation member 334 that is disposed in the rear square installation member 333 and that extends through the rear abutment plate 313, and a second rear resilient member 335 that is sleeved on the rear screw member 331, and that is disposed between and abuts against the head portion of the rear screw member 331 and the rear cylindrical installation member 334. The rear screw member 331 extends through the rear cylindrical installation member 334. The first rear resilient member 332 is disposed between and abuts against the rear installation plate 314 and the rear square installation member 333. The rear screw member 331 extends through the rear square installation member 333. It should be noted that, the number of the rear installation units 33 is not limited to two, and may be not less than one in other embodiments.

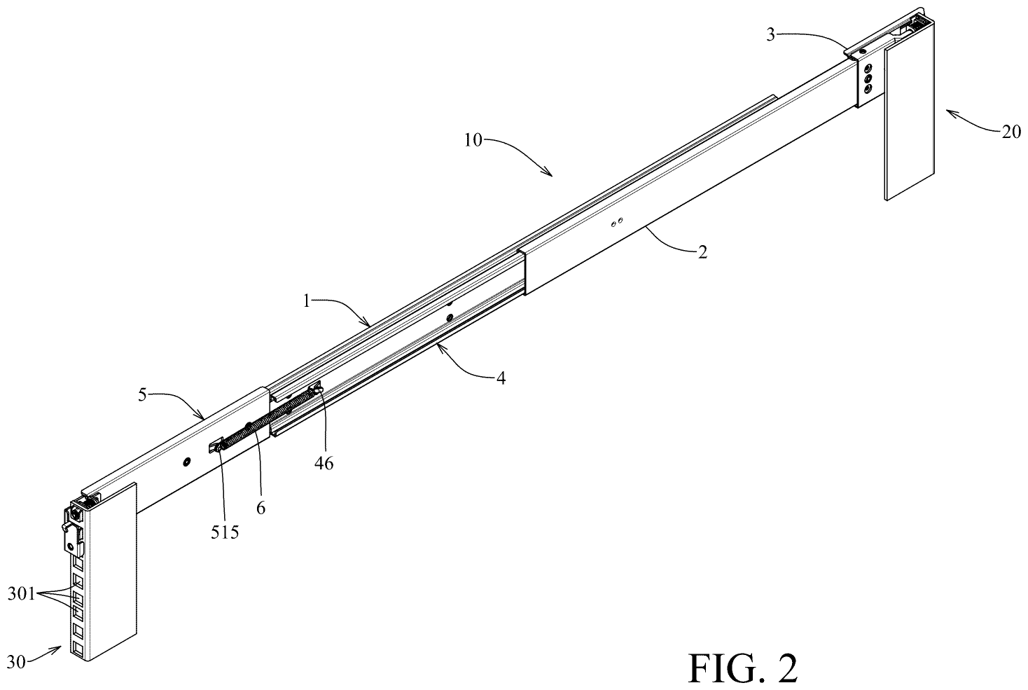

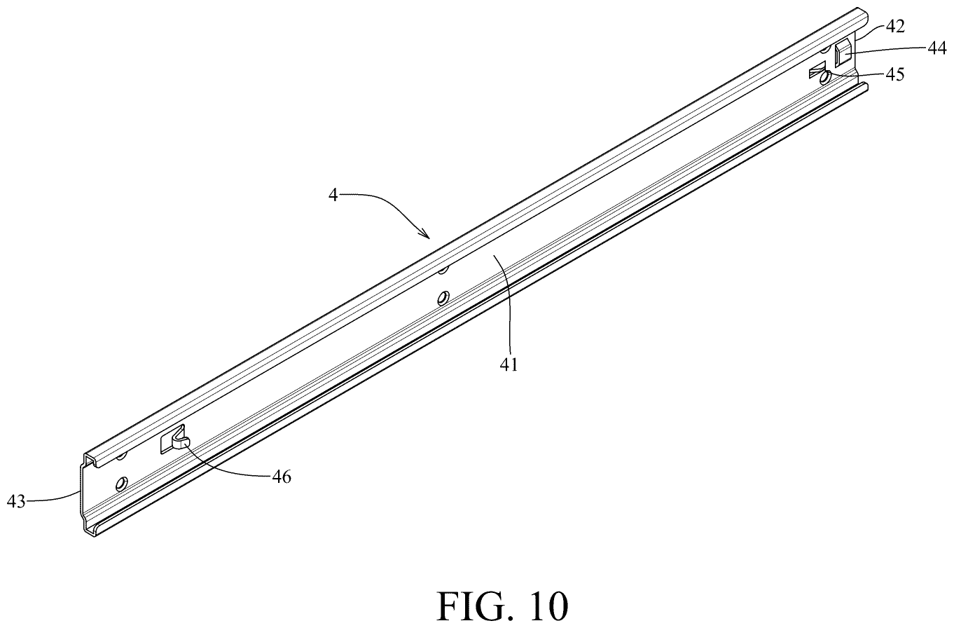

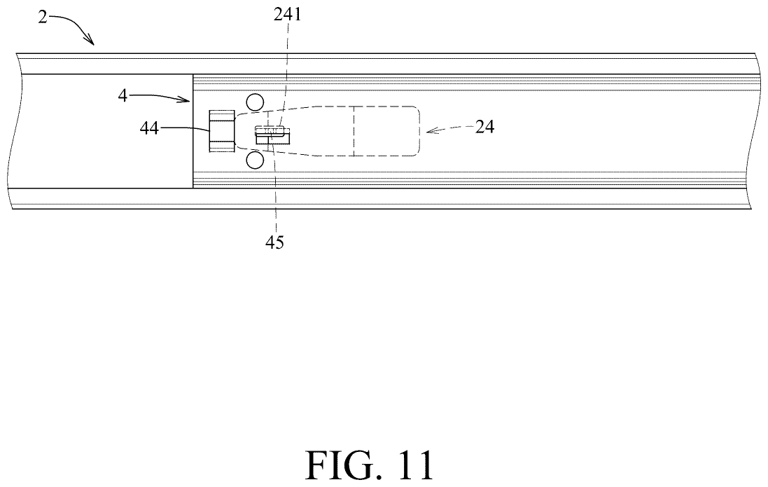

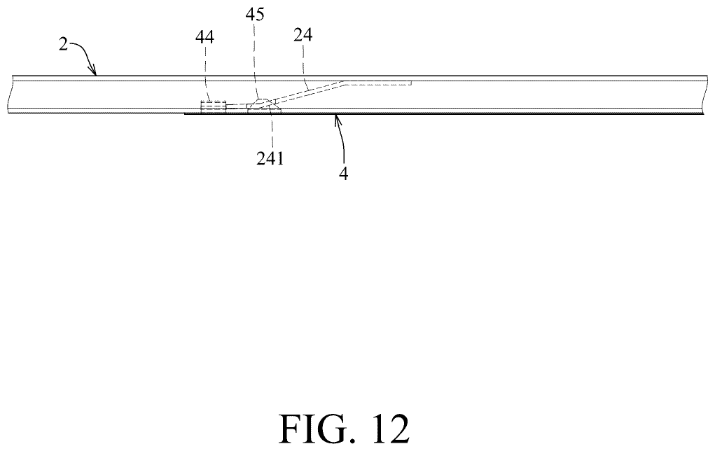

Referring to FIG. 2 and FIGS. 10 to 12, the front support rail 4 is movably disposed on the slide surface 211 of the rear support rail 2, and has an obstruction surface 41 facing the slide surface 211, a first end 42 proximate to the rear support rail 2, a second end 43 opposite to the first end 42 and proximate to the front bracket module 5, an obstruction block 44 formed on the obstruction surface 41, an obstruction protrusion 45 formed on the obstruction surface 41, and a support hook 46 extending from the obstruction surface 41 and proximate to the second end 43. The front support rail 4 is movable relative to the rear support rail 2 for adjusting a length of the sliding rail securing device 10 in accordance to a depth of the cabinet, and in other embodiments, the sliding rail securing device 10 may be mounted to different cabinets with different depths. During movement of the front support rail 4 relative to the rear support rail 2, the obstruction block 44 can abut against the stop member 24, and the obstruction protrusion 45 can engage the through hole 241 of the stop member 24, so as to prevent the front support rail 4 from being disengaged from the rear support rail 2.

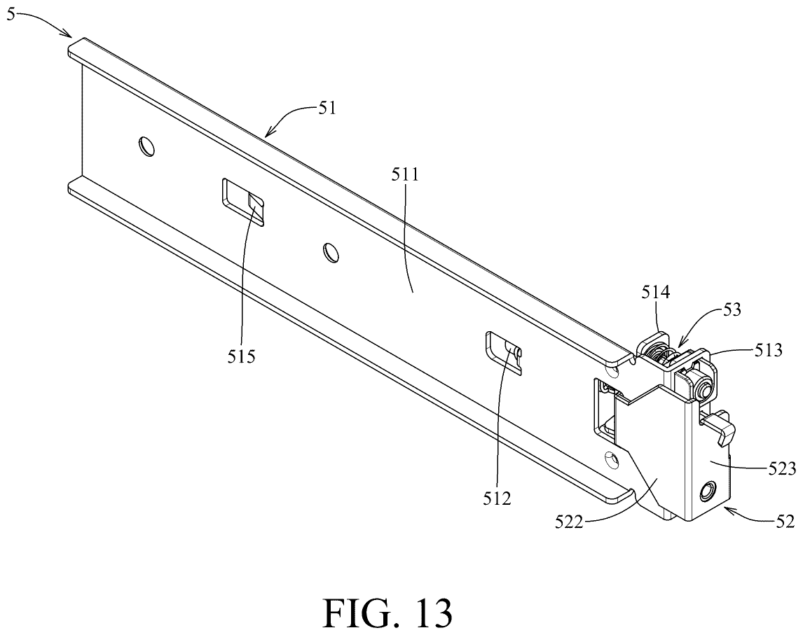

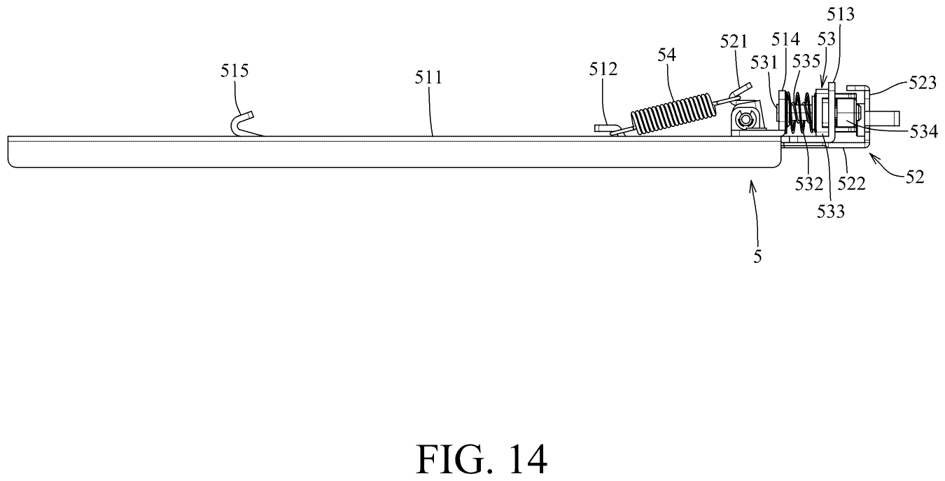

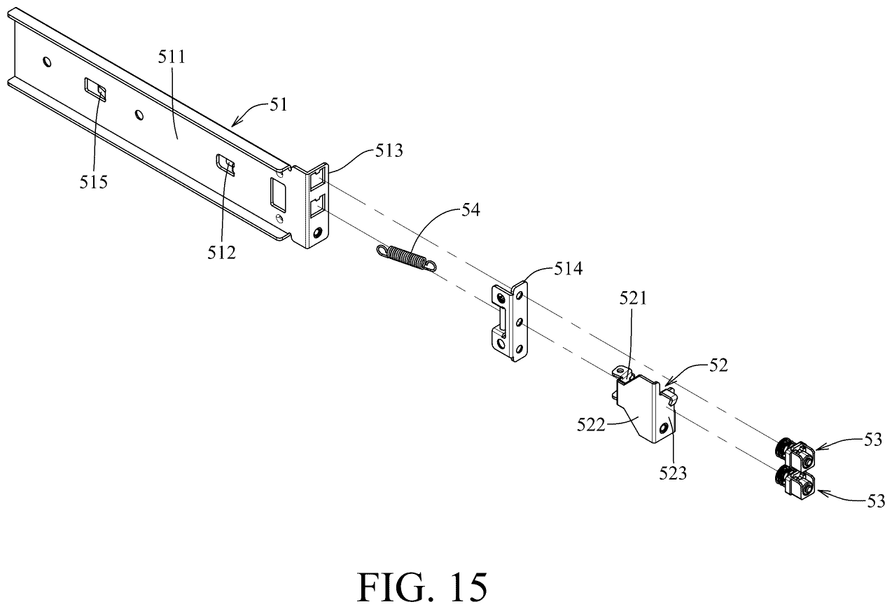

Referring to FIGS. 13 to 15, the front bracket module 5 is adapted to be engaged with the front mount bracket 30 of the cabinet, and includes a front bracket 51 connected to the front support rail 4, a front lock member 52 pivotably mounted to the front bracket 51, at least one front installation unit 53 disposed on the front bracket 51, and a pivot resilient member 54. In this embodiment, the at least one front installation unit 53 includes two front installation units 53. The front bracket 51 has a front base plate 511 connected to the front support rail 4, a first front hook 512 extending from the front base plate 511, a front abutment plate 513 extending transversely from an end of the front base plate 511 opposite to the front support rail 4, a front installation plate 514 mounted to the front base plate 511 and spaced apart from the front abutment plate 513, and a second front hook 515 extending from the front base plate 511 and spaced apart from the first front hook 512. Referring further to FIG. 2, the sliding rail securing device 10 further includes a front connection resilient member 6. The front connection resilient member 6 interconnects the support hook 46 and the first front hook 512. The front lock member 52 is adapted to be engaged with the front mount bracket 30, and has a pivot portion 521 pivotably mounted to the front installation plate 514, a flat plate portion 522 transversely extending from the pivot portion 521, and an engagement plate portion 523 transversely extending from the flat plate portion 522. The pivot resilient member 54 interconnects the first front hook 512 and the pivot portion 521 of the front lock member 52.

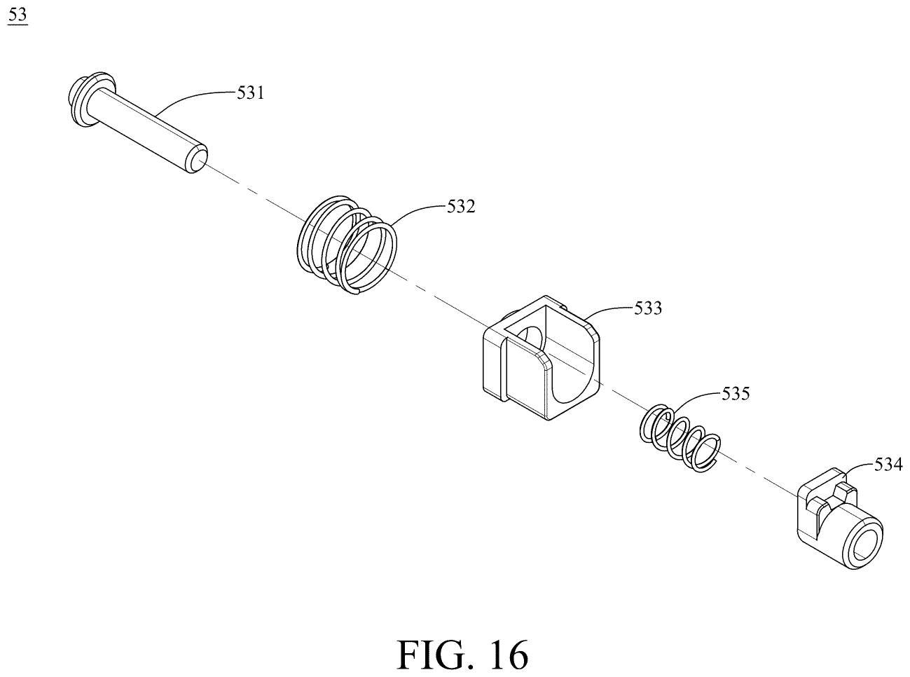

Referring to FIGS. 1, 15, and 16, the front installation units 53 are disposed on the front installation plate 514 and extend through the front abutment plate 513. Each of the front installation units 53 is adapted to be engaged with the front mount bracket 30 via the front mount holes 301, and includes a front screw member 531 that extends through the front abutment plate 513 and the front installation plate 514, and that has a head portion abutting against the front installation plate 514. Each of the front installation units 53 further includes a first front resilient member 532 that is sleeved on the front screw member 531, a front square installation member 533 that extends through the front abutment plate 513, a front cylindrical installation member 534 that is disposed in the front square installation member 533 and that extends through the front abutment plate 513, and a second front resilient member 535 that is sleeved on the front screw member 531, and that is disposed between and abuts against the head portion of the front screw member 531 and the front cylindrical installation member 534. The front screw member 531 extends through the front cylindrical installation member 534. The first front resilient member 532 is disposed between and abuts against the front installation plate 514 and the front square installation member 533. The front screw member 531 extends through the front square installation member 533. It should be noted that, a number of the front installation units 53 is not limited to two, and may be not less than one.

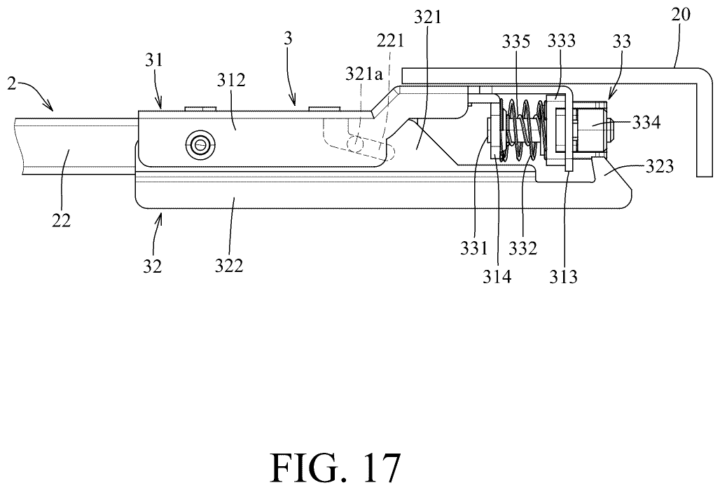

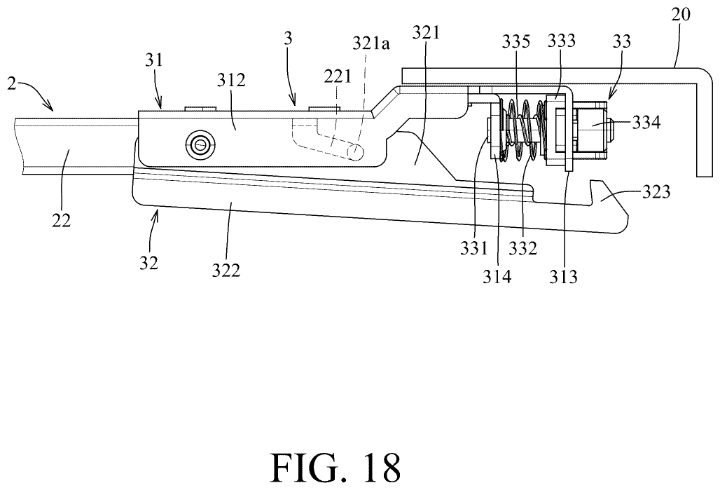

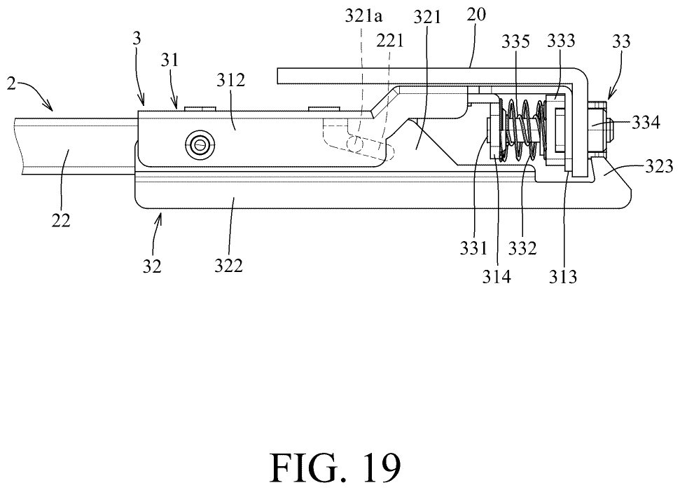

Referring to FIGS. 17 to 19, when the rear bracket module 3 is in an unlocked state and is disposed in front of the rear mount bracket 20 (see FIG. 17), the rear bracket 31 and the rear lock members 32 are rearwardly movable relative to the rear support rail 2 along a rear axis extending in the front-rear direction to drive the protrusions 321a to move respectively along the slide grooves 221, such that the rear lock members 32 are driven to pivot away from the rear bracket 31 from a normal position (see FIG. 17) to a pivoted position (see FIG. 18). The rear bracket 31 and the rear lock members 32 are further rearwardly movable relative to the rear support rail 2 along the rear axis for engaging the rear installation units 33 with the rear mount bracket 20. As shown in FIG. 19, when the rear installation units 33 are engaged with the rear mount bracket 20, the rear lock members 32 are forwardly movable relative to the rear support rail 2 along the rear axis and opposite to the front-rear direction to drive the protrusions 321a to move respectively along the slide grooves 221, such that the rear lock members 32 are driven to pivot from the pivoted position to the normal position for engaging the hook portion 323 of each of the rear lock members 32 with the rear mount bracket 20 and for converting the rear bracket module 3 from the unlocked state to a locked state. The abutment between the positioner member 23 and the one of the limit members 34 generates friction during movement of the rear bracket module 3 relative to the rear support rail 2. The rear bracket module 3 can be moved with one hand of a single operator while the other hand holds the sliding rail securing device 10, and can be engaged with the rear mount bracket 20 without using tools.

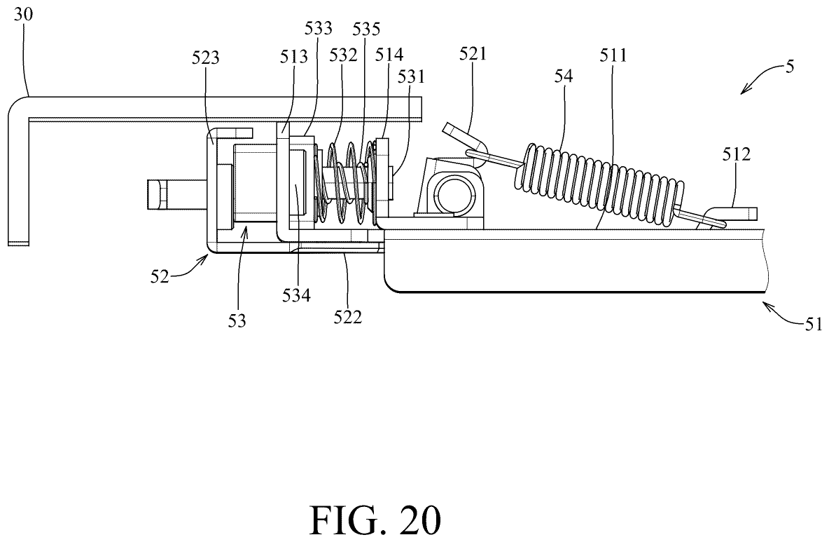

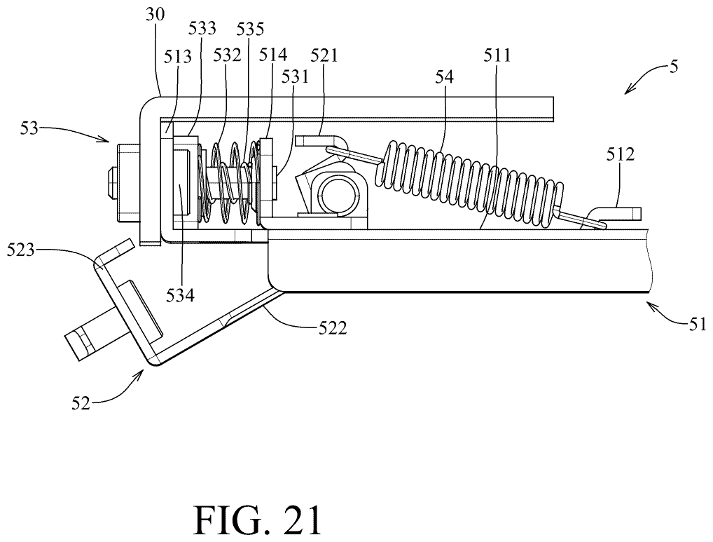

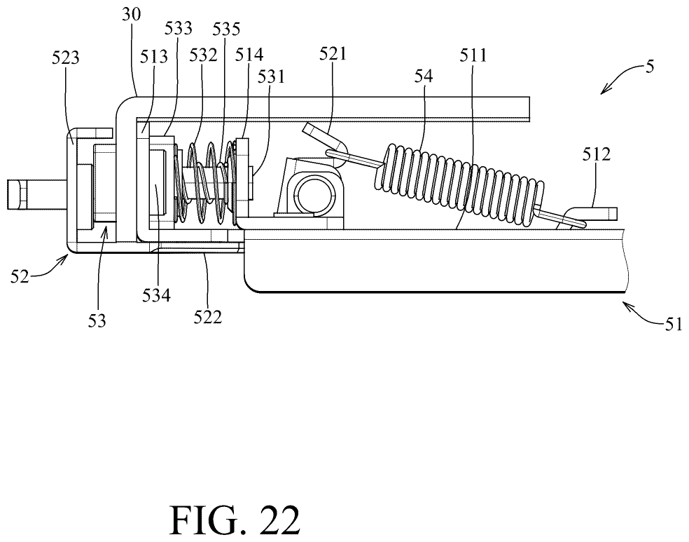

Referring to FIGS. 20 to 22, the front lock member 52 is pivotable relative to the front base plate 511 between a normal position (see FIG. 20), where the flat plate portion 522 is parallel to the front base plate 511, and a pivoted position (see FIG. 21), where the flat plate portion 522 is not parallel to the front base plate 511. When the front lock member 52 is pivoted to the pivoted position, the front bracket module 5 is forwardly movable for engaging the front installation units 53 with the front mount bracket 30. When the front installation units 53 are engaged with the front mount bracket 30, the front lock member 52 is pivotable to the normal position for engaging the engagement plate portion 523 with the front mount bracket 30 and locking the front lock member 52 onto the front mount bracket 30 (see FIG. 22). The front lock member 52 is pivotable by hand, and thus the front bracket module 5 can be engaged with the front mount bracket 30 without using tools.

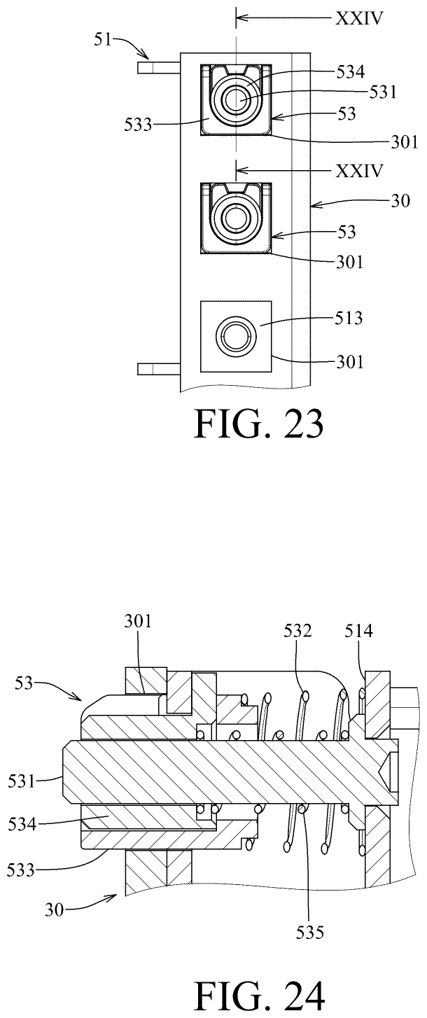

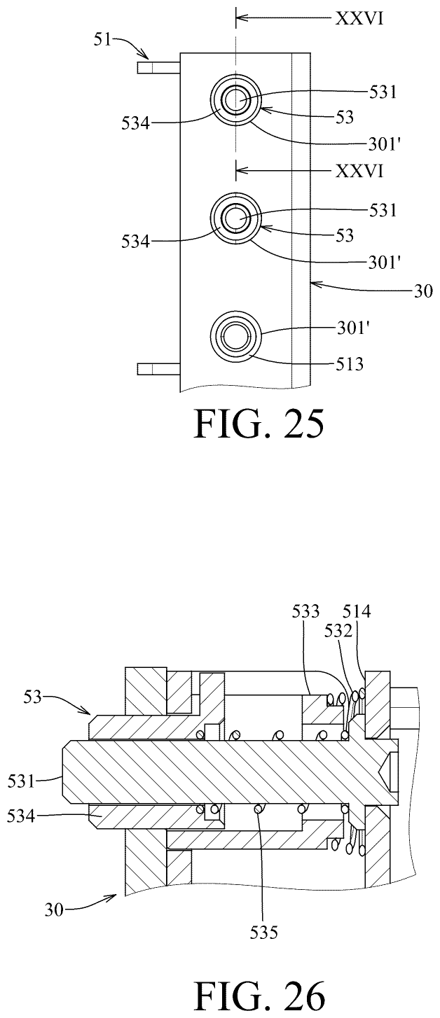

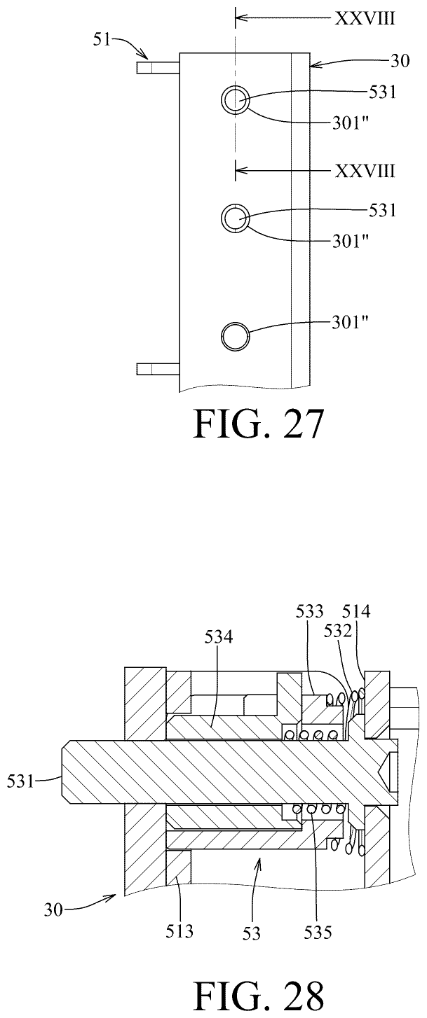

Referring to FIGS. 23 and 24, it should be noted that each of the rear installation units 33 is identical to each of the front installation units 53. Since all of the rear installation units 33 and the front installation units 53 are identical, only one front installation unit 53 will be described in the following for the sake of brevity. In an embodiment where each of the front mount holes 301 has a square shape, the front square installation member 533, the front cylindrical installation member 534 and the front screw member 531 are adapted to extend through a corresponding one of the front mount holes 301 for engagement with the front mount bracket 30. Referring to FIGS. 25 and 26, in another embodiment where each of the front mount hole 301′ has a circular shape, the front cylindrical installation member 534 and the front screw member 531 are adapted to extend through a corresponding one of the front mount holes 301′ to engage with the front mount bracket 30, while the front square installation member 533 is displaced from the front cylindrical installation member 534 and the front screw member 531, and is adapted to abut against the front mount bracket 30. At this time, the first front resilient member 532 is compressed and generates a first resilient force for biasing the front square installation member 533 to a position before the front square installation member 533 is displaced. Referring to FIGS. 27 and 28, in another embodiment where each of the front mount holes 301″ is a threaded hole, the front screw member 531 is adapted to extend through a corresponding one of the front mount holes 301″ to engage with the front mount bracket 30, while the front cylindrical installation member 534 and the front square installation member 533 are displaced from the front screw member 531, and are adapted to abut against the front mount bracket 30. At this time, the first front resilient member 532 generates the first resilient force for biasing the front square installation member 533 to the position before the front square installation member 533 is displaced, and the second front resilient member 535 generates a second resilient force for biasing the front cylindrical installation member 534 to a position before the front cylindrical installation member 534 is displaced. Hence, the front installation unit 53 can be used for engagement with front mount holes having different shapes.

In conclusion, when the rear bracket module 3 is in an unlocked state and is disposed in front of the rear mount bracket 20, the rear bracket 31 and the rear lock members 32 are rearwardly movable relative to the rear support rail 2 along the rear axis extending in the front-rear direction to drive the protrusions 321a to move respectively along the slide grooves 221, such that the rear lock members 32 are driven to pivot away from the rear bracket 31 from the normal position to the pivoted position. The rear bracket 31 and the rear lock members 32 are further rearwardly movable relative to the rear support rail 2 along the rear axis for engaging the rear installation units 33 with the rear mount bracket 20. When the rear installation units 33 are engaged with the rear mount bracket 20, the rear lock members 32 are forwardly movable relative to the rear support rail 2 along the rear axis and opposite to the front-rear direction to drive the protrusions 321a to move respectively along the slide grooves 221, such that the rear lock members 32 are driven to pivot from the pivoted position to the normal position for engaging the hook portion 323 of each of the rear lock members 32 with the rear mount bracket 20 and for converting the rear bracket module 3 from the unlocked state to a locked state. Since the rear bracket module 3 can be engaged with the rear mount bracket 20 without using tools, and only a single operator is needed to engage the rear bracket module 3 with the rear mount bracket 20, the objective of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A sliding rail securing device adapted for mounting a sliding rail to a rear mount bracket of a cabinet, said sliding rail securing device comprising:
a rear support rail that has
a rear base wall having a front end and a rear end that is opposite to said front end in a front-rear direction, and a slide surface that is disposed between said front end and said rear end, and
two rear side walls extending respectively and transversely from opposite top and bottom sides of said slide surface, at least one of said rear side walls being formed with a slide groove that extends away from said slide surface and towards said rear end of said rear base wall; and
a rear bracket module that includes
a rear bracket movably disposed on said rear support rail,
at least one rear lock member pivotably disposed on said rear bracket, adapted to be engaged with the rear mount bracket, and having a protrusion that is movably engaged with said slide groove of said at least one of said rear side walls, and
at least one rear installation unit mounted to said rear bracket and adapted to be engaged with the rear mount bracket;
wherein, when said rear bracket module is in an unlocked state and is disposed in front of the rear mount bracket, said at least one rear lock member is rearwardly movable relative to said rear support rail along a rear axis extending in the front-rear direction to drive said protrusion to move along said slide groove, such that said at least one rear lock member is driven to pivot away from said rear bracket from a normal position to a pivoted position;
wherein said at least one rear lock member is further rearwardly movable relative to said rear support rail along the rear axis for engaging said at least one rear installation unit with the rear mount bracket; and
wherein, when said at least one rear installation unit is engaged with the rear mount bracket, said at least one rear lock member is forwardly movable relative to said rear support rail along the rear axis and opposite to the front-rear direction to drive said protrusion to move along said slide groove, such that said at least one rear lock member is driven to pivot from the pivoted position to the normal position for being engaged with the rear mount bracket and converting said rear bracket module from the unlocked state to a locked state.

2. The sliding rail securing device as claimed in claim 1, wherein said at least one rear lock member further has a connection portion that is pivotably connected to said rear bracket, an extension portion that extends from said connection portion away from said rear bracket, and a hook portion that extends rearwardly from a rear end of said extension portion, and that is adapted to be engaged with the rear mount bracket when said rear bracket module is in the locked state, said protrusion being formed on said connection portion.

3. The sliding rail securing device as claimed in claim 2, wherein:
said rear bracket includes a rear base plate, two rear side plates extending respectively and transversely from opposite top and bottom sides of said rear base plate, a rear abutment plate extending transversely from an end of said rear base plate that is opposite to said rear support rail, and a rear installation plate mounted to said rear base plate and spaced apart from said rear abutment plate;
at least one of said rear side plates is connected to said connection portion of said at least one rear lock member; and
said at least one rear installation unit is mounted on said rear installation plate and extends through said rear abutment plate.

4. The sliding rail securing device as claimed in claim 3, wherein:
said rear base wall is formed with a position groove;
said rear support rail further has a positioner member that covers said position groove;
said rear bracket module further includes a limit member that extends through said position groove and said rear base plate; and
said limit member abuts against said positioner member.

5. The sliding rail securing device as claimed in claim 3, wherein said at least one rear installation unit each includes
a rear screw member that extends through said rear abutment plate and said rear installation plate, and that has a head portion abutting against said rear installation plate,
a first rear resilient member that is sleeved on said rear screw member,
a rear square installation member that extends through said rear abutment plate, said first rear resilient member being disposed between and abutting against said rear installation plate and said rear square installation member, said rear screw member extending through said rear square installation member,
a rear cylindrical installation member that is disposed in said rear square installation member and that extends through said rear abutment plate, said rear screw member extending through said rear cylindrical installation member, and
a second rear resilient member that is sleeved on said rear screw member, and that is disposed between and abuts against said head portion of said rear screw member and said rear cylindrical installation member.

6. The sliding rail securing device as claimed in claim 1, further comprising a front support rail that is movably disposed on said slide surface of said rear support rail, and a front bracket module that is connected to said front support rail and that is adapted to be engaged with a front mount bracket of the cabinet.

7. The sliding rail securing device as claimed in claim 6, wherein said front bracket module includes a front bracket connected to said front support rail, a front lock member pivotably mounted to said front bracket, and at least one front installation unit disposed on said front bracket, said front lock member and said at least one front installation unit being adapted to be engaged with the front mount bracket.

8. The sliding rail securing device as claimed in claim 7, wherein said front bracket has a front base plate connected to said front support rail, a front abutment plate extending transversely from an end of said front base plate opposite to said front support rail, and a front installation plate mounted to said front base plate and spaced apart from said front abutment plate, said at least one front installation unit being disposed on said front installation plate and extending through said front abutment plate.

9. The sliding rail securing device as claimed in claim 8, wherein:
said front bracket further has a first front hook extending from said front base plate;
said front lock member has a pivot portion pivotably mounted to said front installation plate, a flat plate portion transversely extending from said pivot portion, and an engagement plate portion transversely extending from said flat plate portion;
said front bracket module further includes a pivot resilient member interconnecting said first front hook and said pivot portion of said front lock member;
said front lock member is pivotable relative to said front base plate between a normal position, where said flat plate portion is parallel to said front base plate, and a pivoted position, where said flat plate portion is not parallel to said front base plate;
when said front lock member is pivoted to the pivoted position, said front bracket module is forwardly movable for engaging said at least one front installation unit with the front mount bracket; and
when said at least one front installation unit is engaged with the front mount bracket, said front lock member is pivotable to the normal position for engaging said engagement plate portion with the front mount bracket and locking said front lock member onto the front mount bracket.

10. The sliding rail securing device as claimed in claim 8, wherein said at least one front installation unit each includes
a front screw member that extends through said front abutment plate and said front installation plate, and that has a head portion abutting against said front installation plate,
a first front resilient member that is sleeved on said front screw member,
a front square installation member that extends through said front abutment plate, said first front resilient member being disposed between and abutting against said front installation plate and said front square installation member, said front screw member extending through said front square installation member,
a front cylindrical installation member that is disposed in said front square installation member and that extends through said front abutment plate, said front screw member extending through said front cylindrical installation member, and
a second front resilient member that is sleeved on said front screw member, and that is disposed between and abuts against said head portion of said front screw member and said front cylindrical installation member.

11. The sliding rail securing device as claimed in claim 6, wherein:
said rear support rail further has a stop member disposed on said slide surface;
said front support rail has an obstruction surface facing said rear support rail, and an obstruction block formed on said obstruction surface; and
said obstruction block is operable to abut against said stop member.

12. The sliding rail securing device as claimed in claim 11, wherein said stop member has a through hole, said front support rail further having an obstruction protrusion that is formed on said obstruction surface and that is operable to engage said through hole.
